(19) United States
(12) Patent Application Publication
(10) Pub. No.: US 2025/0309182 A1
(43) Pub. Date: Oct. 2, 2025

(54) SEMICONDUCTOR-PACKAGING DEVICE

(71) Applicant: JUSUNG ENGINEERING CO., LTD., Gwangju-Si, Gyeonggi-Do (KR)

(72) Inventors: Sun Wook KIM, Gwangju-Si, Gyeonggi-Do (KR); Min Jong KEUM, Gwangju-Si, Gyeonggi-Do (KR); Jeong Sik PARK, Gwangju-Si, Gyeonggi-Do (KR); Seok Yun OH, Gwangju-Si, Gyeonggi-Do (KR); Eick Hyun LIM, Gwangju-Si, Gyeonggi-Do (KR); Chul Joo HWANG, Gwangju-Si, Gyeonggi-Do (KR)

(21) Appl. No.: 18/556,881

(22) PCT Filed: Apr. 1, 2022
(86) PCT No.: PCT/KR2022/004671

§ 371 Date: May 3, 2024

(30) Foreign Application Priority Data
Apr. 23, 2021 (KR) 10-2021-0052911

(51) Int. Cl. H01L 23/00; H01L 21/677; H01L 21/68

(52) U.S. Cl. CPC H01L 24/741; H01L 21/67748; H01L 21/6776; H01L 21/682; H01L 24/02; H01L 24/94; H01L 2224/02311; H01L 2224/741; H01L 2224/94

(57) ABSTRACT

Provided is an apparatus for packing a semiconductor, and more particularly, to an apparatus for packing a semiconductor, which packages a semiconductor element in a wafer level packaging manner. The apparatus for packaging the semiconductor includes a loading unit having a space in which a process of disposing a mask member on a wafer including a plurality of semiconductor elements is performed, a deposition unit having a space, in which a process of transferring the wafer and the mask member from the loading unit to form a conductive pattern layer on the wafer is performed, and connected to the loading unit, and an unloading unit having a space, in which a process of transferring the wafer and the mask member from the deposition unit to separate the mask member from the wafer is performed, and connected to the deposition unit.

### TECHNICAL FIELD

The present disclosure relates to an apparatus for packing a semiconductor, and more particularly, to an apparatus for packing a semiconductor, which packages a semiconductor element in a wafer level packaging manner.

### BACKGROUND ART

A packaging process refers to a process of packaging a semiconductor element to protect the semiconductor element from external environments. In such a packaging process, a process of forming a conductive pattern so as to arrange lines of the semiconductor element so that a signal is received from and transmitted into an external device is involved.

In the existing packaging process, a wafer including a plurality of semiconductor elements is cut along a dicing line to divide the semiconductor element into individual semiconductor elements, and then, a packaging process is performed for each divided individual semiconductor element. The existing packaging process has to be performed into a chip unit, it takes a very long time to package all the semiconductor elements.

Thus, in recent years, after a packaging process is performed in a state of a wafer including the plurality of semiconductor elements, the wafer level packaging manner in which the wafer is diced for each semiconductor element is being used.

In the apparatus for packaging the semiconductor using the wafer level packaging manner, a conductive pattern for arranging lines of the semiconductor element is generally formed through a photolithography process. However, in the photolithography process, there is a limitation in that it is difficult to effectively reduce a time required for packaging the semiconductor element because each of complicated processes, in which a photoresist is applied on the wafer to perform exposing, developing, and etching processes, and then, the photoresist is removed, has to be performed.

### RELATED ART DOCUMENT

(Patent document 1) KR10-2001-0061786 A

### DISCLOSURE

### Technical Problem

The present disclosure provides an apparatus for packaging a semiconductor, which is capable of improving productivity of a semiconductor element.

### Technical Solution

In accordance with an exemplary embodiment, an apparatus for packaging a semiconductor includes: a loading unit having a space in which a process of disposing a mask member on a wafer including a plurality of semiconductor elements is performed; a deposition unit having a space, in which a process of transferring the wafer and the mask member from the loading unit to form a conductive pattern layer on the wafer is performed, and connected to the loading unit; and an unloading unit having a space, in which a process of transferring the wafer and the mask member from the deposition unit to separate the mask member from the wafer is performed, and connected to the deposition unit.

The loading unit may be connected to one side of the deposition unit, and the unloading unit may be connected to the other side of the deposition unit, which is opposite to the one side of the deposition unit.

The loading unit may include: a first loadlock part connected to the deposition unit; a first wafer storage part having a space, in which a plurality of wafers are stored, and connected to the first loadlock part; a first mask storage part having a space, in which a plurality of mask members are stored, and connected to the first loadlock part; and an alignment part having a space, in which the wafer and the mask member are respectively transferred from the first wafer storage part and the first mask storage part to align and fix the mask member on the wafer, and connected to the first loadlock part.

The deposition unit may include: a deposition chamber configured to provide at least a portion of the space, in which a process of forming the conductive pattern layer on the wafer is performed; a support part installed inside the deposition chamber to support the transferred wafer and mask member; a sputtering target part installed inside the deposition chamber to face the support part; and a power supply part configured to supply power to the sputtering target part.

The support part may include a moving member configured to move the transferred wafer and mask member.

The moving member may include a roller plate or a conveyor belt.

The support part may have a seating surface on which the plurality of wafers are seated.

The deposition unit may include: a first deposition part connected to the loading unit to form a lower conductive pattern layer on a passivation layer formed on the wafer; and a second deposition part connected to the first deposition part to form an upper conductive pattern layer, which is made of a material different from that of the lower conductive pattern layer, on the lower conductive pattern layer.

The second deposition part may be provided in plurality to be interconnected.

The unloading unit may include: a second loadlock part connected to the deposition unit; a second wafer storage part having a space, in which a plurality of wafers are stored, and connected to the second loadlock part; a second mask storage part having a space, in which a plurality of mask members are stored, and connected to the second loadlock part; and a separation part having a space, in which the wafer and the mask member are transferred from the second loadlock part to separate the mask member from the wafer, and connected to the second loadlock part.

The apparatus may further include a transfer unit configured to connect the unloading unit to the loading unit so that the mask member is unloaded from the unloading unit and loaded into the loading unit.

The transfer unit may include a cleaning part configured to clean the mask member unloaded from the unloading unit.

### Advantageous Effects

According to the apparatus for packaging the semiconductor in accordance with the exemplary embodiment, the conductive pattern layer may be formed on the wafer including the plurality of semiconductor elements through the single process using the mask member provided separately from the wafer to minimize the number of processes for forming the conductive pattern layer.

Therefore, the time taken to package the semiconductor element may be minimized to minimize the costs of the materials used in the process, thereby improving the productivity of the semiconductor chip.

### BRIEF DESCRIPTION OF THE DRAWINGS

FIG. 1 is a schematic view illustrating an apparatus for packaging a semiconductor in accordance with an exemplary embodiment;

FIGS. 2 and 3 are views illustrating a state in which a conductive layer is disposed on a wafer in accordance with an exemplary embodiment;

FIG. 4 is a view illustrating a specific structure of the apparatus for packaging the semiconductor in accordance with an exemplary embodiment; and

FIG. 5 is a schematic view of a deposition unit in accordance with an exemplary embodiment.

### MODE FOR CARRYING OUT THE INVENTIVE CONCEPT

Hereinafter, exemplary embodiments of the present inventive concept will be described in detail with reference to the accompanying drawings. The present inventive concept may, however, be embodied in different forms and should not be construed as limited to the exemplary embodiments set forth herein. Rather, these embodiments are provided so that the present inventive concept will be thorough and complete, and will fully convey the scope of the present inventive concept to those skilled in the art. In the figures, the dimensions of layers and regions may be exaggerated for clarity of illustration. Like reference numerals refer to like elements throughout.

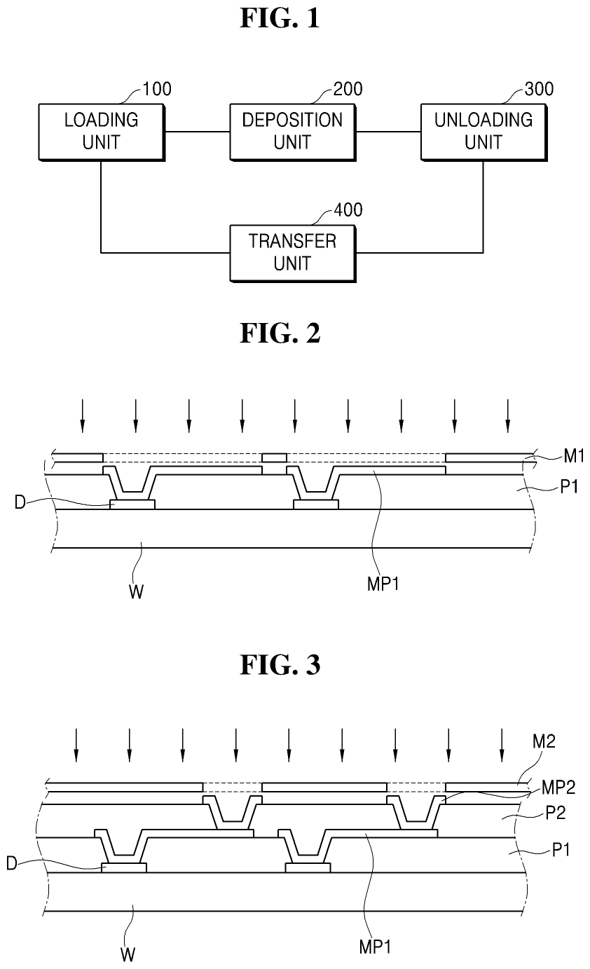

FIG. 1 is a schematic view illustrating an apparatus for packaging a semiconductor in accordance with an exemplary embodiment, and FIGS. 2 and 3 are views illustrating a state in which a conductive layer is disposed on a wafer in accordance with an exemplary embodiment.

Referring to FIGS. 1 to 3, an apparatus for packaging a semiconductor in accordance with an embodiment includes a loading unit 100 having a space, in which a process of disposing a mask member M1 or M2 on a wafer W including a plurality of semiconductor elements is performed, a deposition unit 200 having a space, in which the wafer W and the mask member M1 or M2 is transferred from the loading unit 100 to form a conductive pattern layer MP1 or MP2 on the wafer W, and connected to the loading unit 100, and an unloading unit 300 having a space, in which the wafer W and the mask member M1 or M2 is transferred from the deposition unit 200 to separate the mask member M1 or M2 from the wafer W, and connected to the deposition unit 200.

In the existing packaging process, the wafer including the plurality of semiconductor elements is cut along a dicing line to divide the semiconductor element into individual semiconductor elements, and then, a packaging process is performed for each divided individual semiconductor element. The existing packaging process has to be performed into a chip unit, it takes a very long time to package all the semiconductor elements.

Here, the apparatus for packaging the semiconductor in accordance with an embodiment may be an apparatus that performs a packaging process in a wafer level packaging manner. Here, the wafer level packaging manner refers to a manner of first performing the packaging process in a state of the wafer including the plurality of semiconductor elements and then dicing the wafer for each semiconductor element.

In the wafer level packaging manner in accordance with the related art, a conductive pattern for arranging lines of the semiconductor element in a photolithography manner is formed. However, in this photolithography manner, this photolithography manner has a limitation in that it takes a very long time to package the wafer W because of complicated processes, in which a photoresist is applied on the wafer to perform exposing, developing, and etching processes, and then, the photoresist is removed.

Thus, the apparatus for packaging the semiconductor in accordance with an embodiment may form the conductive pattern layer on the wafer W, on which the plurality of semiconductor elements are formed, by using the mask member M1 or M2, thereby minimize the number of processes for forming the conductive pattern layer.

For example, as illustrated in FIG. 2, the apparatus for packaging the semiconductor in accordance with an embodiment may form a first conductive pattern layer MP1 on an exposed area formed on a first passivation layer P1.

To form the first conductive pattern layer MP1, first, the wafer W on which the plurality of semiconductor elements are formed is prepared. Here, the wafer W refers to a form in which the plurality of unit circuits are arranged on one substrate. In this case, each of the unit circuits may refer to a semiconductor element for performing functions such as information conversion, storage, and calculation and a line structure of the semiconductor element.

The first passivation layer P1 exposing at least a portion of input/output pads D of the plurality of semiconductor elements may be formed on the prepared wafer W. The plurality of semiconductor elements may have the input/output pads for electrical connection with an external device, respectively. In this case, the first passivation layer P1 is formed on the plurality of semiconductor elements to expose the input/output pad D of each of the semiconductor elements.

Here, the first passivation layer P1 may be formed by first forming a first passivation film on the wafer W and then patterning the formed first passivation film by a laser drilling or photolithography process or patterning using a mask. At this time, the first passivation layer may be formed of at least one of polyimide (P1), benzo cyclo butene (BCB), poly benz oxazole (PBO), bismaleimidetriazine (BT), phenolic resin, epoxy, silicone, an oxide layer (SiOx), and a nitride layer (SiNx).

The first conductive pattern layer MP1 may be formed on the wafer W using the first mask member M1. Here, the first conductive pattern layer MP1 may include a metal pattern layer having conductivity, and the first mask member M1 may include a shadow mask provided separately from the wafer W.

The first conductive pattern layer MP1 serves to redistribute an electrical path of the semiconductor element. That is, the first conductive pattern layer MP1 redistributes the electrical path of the semiconductor element to electrically connect the semiconductor chip to an external device regardless of a position of the input/output pad D of the semiconductor element. The above-described first conductive pattern layer MP1 may be made of a metal material having high conductivity such as copper, silver, aluminum, nickel, or the like, or made of an alloy material including other components.

In the process of forming the first conductive pattern layer MP1, the first mask member M1 may be disposed on the wafer W, and then, a conductive material such as a metal material may be supplied to the wafer W to pass through the first mask member M1 so as to deposit the conductive material on the wafer W in the same shape as the pattern of the first mask member M1, thereby forming the first conductive pattern layer MP1.

Also, as illustrated in FIG. 3, the apparatus for packaging the semiconductor in accordance with an embodiment may form a second conductive pattern layer MP2 on an exposed area formed on a second passivation layer P2.

To form the second conductive pattern layer MP2, first, the second passivation layer P2 is formed on the first conductive pattern layer MP1. In the process of forming the second passivation layer P2, a second passivation film may be formed first on the first conductive pattern layer MP1, and then, the second passivation film may be patterned by a laser drilling or photolithography process or may be directly patterned using the mask to form the second passivation layer P2. At this time, the second passivation layer P2 may be formed of at least one of polyimide (P1), benzo cyclo butene (BCB), poly benz oxazole (PBO), bismalcimidetriazine (BT), phenolic resin, epoxy, silicone, an oxide layer (SiOx), and a nitride layer (SiNx).

Here, the second passivation layer P2 may be made of a material different from that of the first passivation layer P1. When the first passivation layer P1 and the second passivation layer P2 are formed of materials different from each other, penetrated moisture, etc., may move along a boundary between the layers formed of the materials different from each other to increase in moving distance. Thus, the moisture, etc., may be prevented from being penetrated.

After the second passivation layer P2 is formed, a process of forming the second conductive pattern layer MP2 on the second passivation layer P2 may be performed. The second conductive pattern layer MP2 may be formed on the exposed area formed on the second passivation layer P2, and the second conductive pattern layer MP2 may be formed using the second mask member M2. Here, like the first conductive pattern layer MP1, the second conductive pattern layer MP2 may include a metal pattern layer having conductivity, and the second mask member M2 may include a shadow mask provided separately from the wafer W.

Here, the second conductive pattern layer MP2 serves as a seed layer for forming a conductive bumps. As described above, the second conductive pattern layer MP2 may be made of a metal material such as copper, silver, aluminum, nickel, chromium, titanium, or tungsten, or an alloy material including other components. In addition, the second conductive pattern layer MP2 may be formed by laminating a plurality of layers, and in this case, a plurality of layers made of chromium, a chromium-copper alloy, and a copper material, a plurality of layers made of a titanium-tungsten alloy and a copper material, or a plurality of layers made of aluminum, nickel, and copper materials may be laminated to form the second conductive pattern layer MP2.

That is, in the process of forming the second conductive pattern layer MP2, the second mask member M2 may be disposed on the wafer W, on which the second passivation layer P2 is formed, and a second conductive material may be supplied to the wafer W to pass through the second mask member M2 so as to form the second conductive pattern layer MP2 on the second passivation layer P2 having the same shape as the pattern of the second mask member M2. Although not shown, after forming the second conductive pattern layer MP2, a conductive bump may be formed on the second conductive pattern layer MP2. After the conductive bump is formed, the wafer W may be cut for each semiconductor element to form a plurality of semiconductor chips.

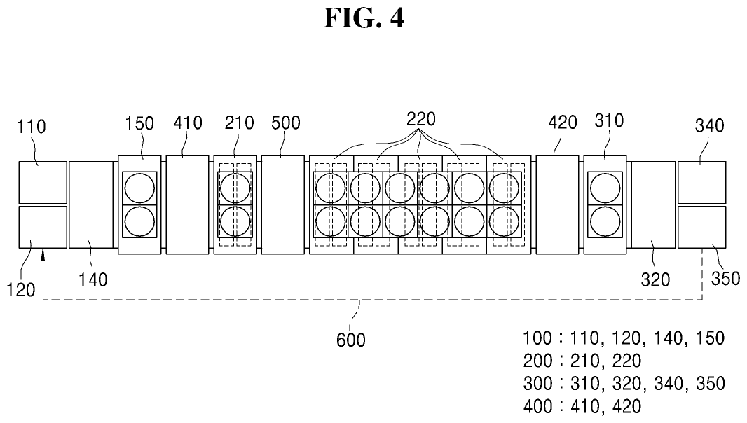

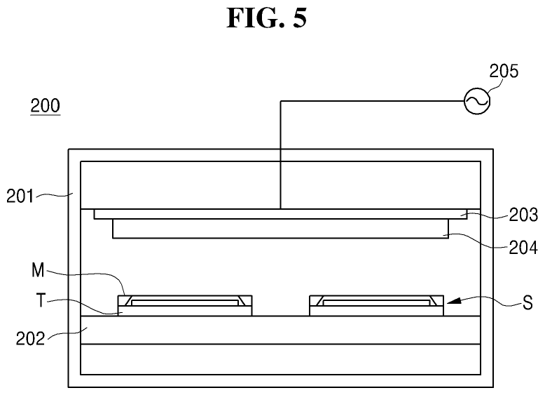

As described above, in the apparatus for packaging the semiconductor in accordance with an embodiment of the present inventive concept, the first conductive pattern layer MP1 or the second conductive pattern layer MP2 may be formed on the wafer, on which the plurality of semiconductor elements are formed, by using the mask member M1 or M2. The detailed structure of the apparatus for packaging the semiconductor, which forms the first conductive pattern layer MP1 or the second conductive pattern layer MP2, in accordance with an embodiment will be described in detail below with reference to FIGS. 4 and 5.

FIG. 4 is a view illustrating a specific structure of the apparatus for packaging the semiconductor in accordance with an exemplary embodiment, and FIG. 5 is a schematic view of a deposition unit in accordance with an exemplary embodiment.

As described above, the apparatus for packaging the semiconductor in accordance with an embodiment includes the loading unit 100 having the space, in which the process of disposing the mask member M (M1 or M2) on the wafer W including the plurality of semiconductor elements is performed, the deposition unit 200 having the space, in which the wafer W and the mask member M is transferred from the loading unit 100 to form the conductive pattern layer MP1 or MP2 on the wafer W, and connected to the loading unit 100, and the unloading unit 300 having the space, in which the wafer W and the mask member M is transferred from the deposition unit 200 to separate the mask member M from the wafer W, and connected to the deposition unit 200.

In the apparatus for packaging the semiconductor in accordance with an embodiment of the present inventive concept, the loading unit 100, the deposition unit 200, and the unloading unit 300 may be disposed in a cluster type, but may be disposed in an in-line type, in which the loading unit 100 is connected to one side of the deposition unit 200, and the unloading unit 300 is connected to the other side of the deposition unit 200, to increase in process speed and improve productivity. In this case, the one side and the other side of the deposition unit 200 may be opposite to each other.

The loading unit 100 has a space in which a process of disposing the mask member M on the wafer W including the plurality of semiconductor elements is performed. For this, the loading unit 100 may include a first loadlock part 150 connected to the deposition unit 200, a first wafer storage part 110 having a space, in which a plurality of wafers W are stored, and connected to the first loadlock part 150, a first mask storage part 120 having a space, in which a plurality of mask members M are stored, and connected to the first loadlock part 150, and an alignment part 140 having a space, in which the wafer W and the mask member M are respectively transferred from the first wafer storage part 110 and the first mask storage part 120 to align and fix the mask member M on the wafer W, and connected to the first loadlock part 150. Here, the alignment part 140 may include a first robot arm (not shown) for transferring the wafer W and the mask member M between each of the first wafer storage part 110 and the first mask storage part 120 and the first loadlock part 150.

The first wafer storage part 110 may include a first wafer storage chamber and a first wafer storage cassette provided inside the first wafer storage chamber. The wafer W on which a plurality of unit circuits are formed may be stored in the first wafer storage cassette. Here, the wafer W may be a wafer W on which the first passivation layer P1 is formed to cover the plurality of unit circuits or may be a wafer W on which the first conductive pattern layer MP1 and the second passivation layer P2 are further formed on the first passivation layer P1. A plurality of wafers W may be stored in the first wafer storage cassette in a vertical direction.

The first mask storage part 120 may include a first mask storage chamber and a first mask storage cassette disposed inside the first mask storage chamber. The first mask member M1 or the second mask member M2 may be stored in the first mask storage cassette. The plurality of mask members M may be stored in the vertical direction.

The alignment part 140 has a space in which the wafer W and the mask member M are respectively transferred from the first wafer storage part 110 and the first mask storage part 120 to align and fix the mask member M on the wafer W. As described above, the alignment part 140 may include an alignment chamber and also may include the first robot arm disposed in the alignment chamber. Here, the first robot arm may respectively unload the wafer W and the mask member M from the first wafer storage part 110 and the first mask storage part 120 to transfer the wafer W and the mask member M to the first loadlock part 150. Hereinafter, although the configuration in which the alignment part 140 includes the first robot arm to align the mask member M on the wafer W while the wafer W and the mask member M respectively unloaded from the first wafer storage part 110 and the first mask storage part 120 moves to the first loadlock part 150 is described as an example, the alignment part 140 may be provided separately from a space, in which the first robot arm is disposed, to receive the wafer W and the mask member M from the first robot arm, thereby aligning and fixing the mask member M on the wafer W.

The alignment part 140 respectively unloads the wafer W and the mask member M from the first wafer storage part 110 and the first mask storage part 120 to align the mask member M on the wafer W and then transfer the wafer W and the mask member M, which are aligned with each other, to the first loadlock part 150. The alignment part 140 may have various configurations for aligning and fixing the mask member M on the wafer W. For example, as illustrated in FIG. 5, the alignment part 140 may be configured so that the wafer W is seated on a tray T, and the mask member M is aligned on the wafer W, and then, the tray T and the mask member M are fixed by magnetic force to align and fix the mask member M on the wafer W. Here, a plurality of trays T may be stored in the alignment part 140, or the tray T may be inserted into the alignment part 140 through the first robot ram from a tray storage part (not shown) disposed separately from the alignment part 140.

One side of the first loadlock part 150 may be connected to the alignment part 140, and the other side of the first loadlock part 150 may be connected to the deposition unit 200. The first loadlock part 150 may receive the tray T from the alignment part 140 under an atmospheric pressure state and may transfer the tray T to the deposition unit 200 after being converted to a vacuum state. Although not shown, for example, the first loadlock part 150 may include a first atmospheric pressure loadlock having one side connected to the alignment part 140 and a first vacuum loadlock having one side connected to the other side of the first atmospheric pressure loadlock and the other side connected to the deposition unit 200.

The inside of the first atmospheric pressure loadlock may be created at the atmospheric pressure, and also, the inside of each of the first wafer storage part 110, the first mask storage part 120, the alignment part 140, and the first robot arm, which directly or indirectly connected to the first atmospheric pressure loadlock may be created at the atmospheric pressure. The first atmospheric pressure loadlock may receive the tray T, in which the mask member M is fixed on the wafer W, from the first robot arm to transfer the tray T to the first vacuum loadlock. Here, the first atmospheric pressure loadlock may simultaneously or sequentially receive the plurality of trays T, on which the mask member M is fixed on the wafer W, to simultaneously or sequentially transfer the plurality of trays T to the first vacuum loadlock. The inside of the first vacuum loadlock is adjusted to be changed from the atmospheric pressure state to the vacuum state and also receive the plurality of trays T from the first atmospheric pressure loadlock to transfer the trays T to the deposition unit 200.

The deposition unit 200 is connected to the loading unit 100 and has a space in which a process of receiving the wafer W and the mask member M, which are seated on the tray T, from the loading unit 100 to form the conductive pattern layer MP1 or MP2 on the wafer W is performed. For this, as illustrated in FIG. 5, the deposition unit 200 may include a deposition chamber 201 providing at least a portion of the space, in which the process of forming the conductive pattern layer MP1 or MP2 on the wafer W is performed, a support part 202 installed inside the deposition chamber 201 to support the transferred wafer W and mask member M, a sputtering target part 204 installed inside the deposition chamber to face the support part 202, and a power supply part 205 for supplying power to the sputtering target part 204.

The deposition chamber 201 forms a process space in which a deposition process is performed, and the deposition chamber 201 may be connected to a predetermined vacuum pump (not shown) to maintain a vacuum therein.

A gas supply tube (not shown) for supplying an inert gas, for example, an argon (Ar) gas, etc. may be connected to the deposition chamber 201. The gas supply tube may be connected to the deposition chamber 201 to supply the inert gas to a region, in which plasma discharge occurs, that is, a region between the sputtering target part 204 and the wafer W.

The support part 202 is disposed inside the deposition chamber 201 to support the wafer W loaded into the deposition chamber 201. As described above, when receiving the wafer W and the mask member M, which are seated on the tray T, from the loading unit 100, the support part 202 may support and transfer the tray T, on which the wafer W and the mask member M are seated. For this, the support part 202 may include a moving member for moving the received wafer W and mask member M on the tray T. The moving member may include a roller plate or a conveyor belt. In addition, when the plurality of trays T on which the wafer W is seated are simultaneously transferred from the loading unit 100, the support 202 may have a seating surface on which the plurality of wafers W are seated. Thus, the deposition process may be simultaneously performed on the plurality of wafers W to improve productivity.

In addition, the deposition unit 200 may further include a backing plate 203. The backing plate 203 supports the sputtering target part 204 and also allows power to be supplied to the sputtering target part 204. For this, the backing plate 203 may be electrically connected to the power supply part 205, for example, a DC power source, an AC power source, or an RF power source to apply plasma power supplied from the power supply part 205 to the sputtering target part 204.

The sputtering target part 204 is installed inside the deposition chamber 201 to face the support part 202. Here, the sputtering target part 204 may be made of a conductive material for forming the conductive pattern layer MP1 or MP2 on the wafer W and may have an area greater than that of the wafer W. The sputtering target part 204 may be installed on a rear surface of the backing plate 203 so as to be spaced a predetermined distance from the wafer W and to face each other.

Although not shown, the deposition unit 200 may further include a magnetic field generation part installed inside the deposition chamber 201.

The magnetic field generation part may vibrate at a certain period (or width) during the sputtering process and also generate magnetic fields on a surface of the sputtering target part 204 while moving in a predetermined direction to uniformly distribute an erosion area of the sputtering target part 204 on the entire area of the sputtering target part 204 due to the magnetic fields, thereby maximizing use efficiency of the sputtering target part 204. In addition, the magnetic field generation part may generate high-density plasma on the surface of the sputtering target part 204 through the magnetic fields to increase in deposition rate of the conductive pattern layer MP1 or MP2 deposited on the wafer. For this, the magnetic field generation part may include a magnet module and a magnet moving module.

As described above, the deposition unit 200 may include a first deposition part 210 connected to the loading unit 100 to form a lower conductive pattern layer on the passivation layer P1 or P2 formed on the wafer W and a second deposition part 220 connected to the first deposition part 210 to form an upper conductive pattern layer, which is made of a material different from that of the lower conductive pattern layer, on the lower conductive pattern layer. Here, each of the first deposition part 210 and the second deposition part 220 may include the deposition chamber 201, the support part 202, the backing plate 203, the sputtering target part 204, and the power supply part 205, which are described above.

The first deposition part 210 may be connected to the loading unit 100 through a first transfer part 410 that serves to adjust a moving speed of the tray T. Here, the first deposition part 210 may form the lower conductive pattern layer on the passivation layer P1 or P2 formed on the wafer W. Here, the lower conductive pattern layer may be made of a material such as titanium (Ti) to improve adhesion of the first conductive pattern layer MP1 or the second conductive pattern layer MP2 formed on the first passivation layer P1 or the second passivation layer P2.

The second deposition part 220 may be directly connected to the first deposition part 210 or may be connected to the first deposition part 210 through a buffer part 500. The first deposition part 210 is configured to form the lower conductive pattern layer on the passivation layer P1 or P2 formed on the wafer W, and the second deposition part 220 is configured to form the upper conductive pattern layer on the lower conductive pattern layer formed by the first deposition part 210 as described later. Here, the first deposition part 210 and the second deposition part 220 may have different pressure conditions to form the lower conductive pattern layer or the upper conductive pattern layer, and thus, when the pressure conditions of the first deposition part 210 and the second deposition part 220 are different from each other, for example, when a pressure difference between the first deposition part 210 and the second deposition part 220 is large, the pressure may be adjusted in the buffer part 500 between the first deposition part 210 and the second deposition part 220.

The second deposition part 220 may be configured to form the upper conductive pattern layer on the lower conductive pattern layer formed by the first deposition part 210, and the upper conductive pattern layer may be made of a metal material such as copper, silver, aluminum, nickel, chromium, titanium, or tungsten, or an alloy material containing other components. Here, the upper conductive pattern layer may be made of a material different from that of the lower conductive pattern layer to improve adhesion and form the conductive pattern layer MP1 or MP2 having excellent conductivity.

In addition, the upper conductive pattern layer needs to be formed to be thicker than the lower conductive pattern layer to improve the adhesion. For this, a plurality of second deposition parts 220 for forming the upper conductive pattern layer are provided to be interconnected. In this case, the tray T sequentially passes through the plurality of second deposition parts 220, and thus, the upper conductive pattern layer having a sufficient thickness may be formed on the passivation layer P1 or P2. Here, the number of installed second deposition parts 220 may be variously set in accordance with the thickness of the upper conductive pattern layer.

The unloading unit 300 has a space in which a process of transferring the tray T from the deposition unit 200 to separate the mask member M from the wafer W is performed. For this, the unloading unit 300 may include a second loadlock part 310 connected to the deposition unit 200, a second wafer storage part 340 having a space, in which a plurality of wafers W are stored, and connected to the second loadlock part 310, a second mask storage part 350 having a space, in which a plurality of mask members M are stored, and connected to the second loadlock part 310, and a separation part 320 having a space, in which the wafer W and the mask member M are transferred from the second loadlock part 310 to separate the mask member M from the wafer W, and connected to the second loadlock part 310.

The second loadlock part 310 may be connected to the deposition unit 200, for example, the second deposition part 220 through a second transfer part 420, which adjusts the moving speed of the tray T. The second loadlock part 310 may has one side connected to the second deposition part 220 and the other side connected to the separation part 320. As described above, the second loadlock part 310 may receive the tray T from the second deposition part 220 in a vacuum state to transfer the tray T to the separation part 320 after being converted to an atmospheric pressure state. Although not shown, for example, the second loadlock part 310 may include a second vacuum loadlock connected to the second deposition part 220 and a second atmospheric pressure loadlock having one end connected to the second vacuum loadlock and the other end connected to the second vacuum loadlock to be described later and connected to the second robot arm 320.

The second vacuum loadlock is controlled so that the inside thereof is changed from the vacuum state to the atmospheric pressure state, and the plurality of trays T on which the wafers W, on which the conductive pattern layer MP1 or MP2 is formed, are seated are transferred from the deposition unit 200 and then transferred to the second atmospheric pressure loadlock. The inside of the second atmospheric pressure loadlock may be created at the atmospheric pressure, and the inside of each of the separation part 320, the second wafer storage part 340, and the second mask storage part 350, which are connected to the second atmospheric pressure loadlock, may also be created at the atmospheric pressure.

The separation part 320 has a space in which the wafer W and the mask member M seated on the tray T are transferred from the second atmospheric pressure loadlock to separate the mask member M from the wafer W. As described above, the separation part 320 may include a separation chamber and also include a second robot arm disposed in the separation chamber. Here, the second robot arm may receive the wafer W and the mask member M, which are seated on the tray T, from the second atmospheric pressure loadlock to transfer the wafer W and the mask member M to the second wafer storage part 340 and the second mask storage part 350, respectively. Hereinafter, although the configuration in which the separation part 320 includes the second robot arm to separate the wafer W and the mask member M, which are transferred from the second atmospheric pressure loadlock and are seated and fixed on the tray T, to transfer the wafer W and the mask member M to the second wafer storage part 340 and the second mask storage part 350, is described as an example, the separation par 320 may be provided separately from the space, in which the second robot arm is disposed, to receive the wafer W and the mask member M, which are seated and fixed on the tray T, from the second robot arm to separate the wafer W and the mask member M.

As described above, the mask member M may be separated from the wafer W in the separation chamber. For example, the separation part 320 may be separated by releasing the fixing of the tray T and the mask member M, and the separated tray T may be stored in the separation part 320 or may move from the separation part 320 to the above-described tray storage part.

The second wafer storage part 340 may include a second wafer storage chamber and a second wafer storage cassette provided inside the second wafer storage chamber. The deposition of the conductive pattern layer may be completed in the second wafer storage cassette, and the wafer W transferred from the second robot arm may be stored, and the plurality of wafers W, on which the deposition is completed, may be stored in the second wafer storage cassette.

The second mask storage part 350 may include a second mask storage chamber and a second mask storage cassette disposed inside the second mask storage chamber. The first mask member M1 or the second mask member M2 used in the deposition process may be stored in the second mask storage cassette. The plurality of mask members M may be stored in the vertical direction.

The apparatus for packaging the semiconductor in accordance with an embodiment of the present inventive concept may further include a transfer unit 600 connecting the unloading unit 300 to the loading unit 100 so that the used mask member M is unloaded from the unloading unit 300 and then loaded into the loading unit. Here, the transfer part 600 may interconnect the second mask storage part 350 of the unloading unit 300 to the first mask storage part 120 of the loading unit 100. In addition, the transfer part 600 may include a transfer part (not shown) for transferring the mask member M and a cleaning part (not shown) for cleaning the mask member M unloaded from the unloading unit 300. Here, the transfer part of the transfer unit 600 may include a roller plate or a conveyor belt capable of loading the mask member M into the loading unit 100. The cleaning part performs wet or dry cleaning of the used mask member M. As described above, the used mask member M may be cleaned to be loaded into the loading unit 100, thereby preventing the conductive pattern layer from being contaminated by impurities in the subsequent deposition process and improving deposition uniformity.

As described above, in accordance with the apparatus for packaging the semiconductor in accordance with the exemplary embodiment, the conductive pattern layer may be formed on the wafer including the plurality of semiconductor elements through the single process using the mask member provided separately from the wafer to minimize the number of processes for forming the conductive pattern layer.

Therefore, the time taken to package the semiconductor element may be minimized to minimize the costs of the materials used in the process, thereby improving the productivity of the semiconductor chip.

In accordance with the apparatus for packaging the semiconductor in accordance with the exemplary embodiment, the conductive pattern layer may be formed on the wafer including the plurality of semiconductor elements through the single process using the mask member provided separately from the wafer to minimize the number of processes for forming the conductive pattern layer.

Therefore, the time taken to package the semiconductor element may be minimized to minimize the costs of the materials used in the process, thereby improving the productivity of the semiconductor chip.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present inventive concept may belong to the technical spirit of the present inventive concept.

What is claimed is:

1. An apparatus for packaging a semiconductor, the apparatus comprising:
a loading unit having a space in which a process of disposing a mask member on a wafer comprising a plurality of semiconductor elements is performed;
a deposition unit having a space, in which a process of transferring the wafer and the mask member from the loading unit to form a conductive pattern layer on the wafer is performed, and connected to the loading unit; and
an unloading unit having a space, in which a process of transferring the wafer and the mask member from the deposition unit to separate the mask member from the wafer is performed, and connected to the deposition unit.

2. The apparatus for packaging a semiconductor of claim 1, wherein the loading unit is connected to one side of the deposition unit, and the unloading unit is connected to the other side of the deposition unit, which is opposite to the one side of the deposition unit.

3. The apparatus of claim 1, wherein the loading unit comprises:
a first loadlock part connected to the deposition unit;
a first wafer storage part having a space, in which the wafer is stored, and connected to the first loadlock part;
a first mask storage part having a space, in which the mask member is stored, and connected to the first loadlock part; and
an alignment part having a space, in which the wafer and the mask member are respectively transferred from the first wafer storage part and the first mask storage part to align and fix the mask member on the wafer, and connected to the first loadlock part.

4. The apparatus of claim 1, wherein the deposition unit comprises:
a deposition chamber configured to provide at least a portion of the space, in which a process of forming the conductive pattern layer on the wafer is performed;
a support part installed inside the deposition chamber to support the transferred wafer and mask member;
a sputtering target part installed inside the deposition chamber to face the support part; and
a power supply part configured to supply power to the sputtering target part.

5. The apparatus of claim 4, wherein the support part comprises a moving member configured to move the transferred wafer and mask member.

6. The apparatus of claim 5, wherein the moving member comprises a roller plate or a conveyor belt.

7. The apparatus of claim 4, wherein the support part has a seating surface on which the wafer is seated.

8. The apparatus of claim 1, wherein the deposition unit comprises:
a first deposition part connected to the loading unit to form a lower conductive pattern layer on a passivation layer formed on the wafer; and
a second deposition part connected to the first deposition part to form an upper conductive pattern layer, which is made of a material different from that of the lower conductive pattern layer, on the lower conductive pattern layer.

9. The apparatus of claim 8, wherein the second deposition part is provided in plurality to be interconnected.

10. The apparatus of claim 1, wherein the unloading unit comprises:
a second loadlock part connected to the deposition unit;
a second wafer storage part having a space, in which the wafer is stored, and connected to the second loadlock part;
a second mask storage part having a space, in which the mask member is stored, and connected to the second loadlock part; and
a separation part having a space, in which the wafer and the mask member are transferred from the second loadlock part to separate the mask member from the wafer, and connected to the second loadlock part.

11. The apparatus of claim 1, further comprising a transfer unit configured to connect the unloading unit to the loading unit so that the mask member is unloaded from the unloading unit and loaded into the loading unit.

12. The apparatus of claim 11, wherein the loading unit comprises a first mask storage part having a space in which the mask member is stored,
the unloading unit comprises a second mask storage part having a space in which the mask member is stored, and
the transfer unit is configured to connect the first mask storage part to the second mask storage part.

13. The apparatus of claim 11, wherein the transfer unit comprises a cleaning part configured to clean the mask member unloaded from the unloading unit.
